(19) United States
(12) Patent Application Publication
(10) Pub. No.: US 2025/0374590 A1
(43) Pub. Date: Dec. 4, 2025

(54) HIGH VOLTAGE SEMICONDUCTOR DEVICE AND METHOD OF MANUFACTURING SAME

(71) Applicant: DB HiTek Co., Ltd., Bucheon-si (KR)

(72) Inventor: Jung Hyun PARK, Eumseong-gun (KR)

(21) Appl. No.: 18/812,209

(22) Filed: Aug. 22, 2024

(30) Foreign Application Priority Data
Jun. 4, 2024 (KR) 10-2024-0072875

(51) Int. Cl. H01L 29/78; H01L 29/06; H01L 29/40; H01L 29/423; H01L 29/49; H01L 29/66

(52) U.S. Cl. CPC H10D 30/603; H10D 30/0285; H10D 62/115; H10D 64/117; H10D 64/512; H10D 30/0212; H10D 30/022; H10D 64/668

(57) ABSTRACT

A high voltage semiconductor device and a method of manufacturing the same seek to prevent breakdown voltage characteristics of the device from deteriorating by blocking the formation of an impurity doped region within a substrate due to a separation space between a gate region and a dummy gate region during a subsequent process by overlapping gate spacers between the gate region and the dummy gate region.

### CROSS REFERENCE TO RELATED APPLICATION

The present application claims priority to Korean Patent Application No. 10-2024-0072875, filed Jun. 4, 2024, the entire content of which is incorporated herein for all purposes by this reference.

### BACKGROUND OF THE INVENTION

### Field of the Invention

The present disclosure relates to a high voltage semiconductor device and a method of manufacturing the same and, more particularly, to a high voltage semiconductor device and a method of manufacturing the same seeking to prevent breakdown voltage characteristics of the device from deteriorating by blocking the formation of an impurity doped region within a substrate due to a separation space between a gate region and a dummy gate region during a subsequent process by overlapping gate spacers between the gate region and the dummy gate region.

### Description of the Related Art

A lateral double-diffused metal oxide semiconductor (LDMOS) is a representative power device with fast switching response and high input impedance.

FIG. 1 is a cross-sectional view showing a conventional high voltage semiconductor device. Hereinafter, the structure of a conventional high voltage semiconductor device 9 and the resulting problems will be described with reference to FIG. 1.

Referring to FIG. 1, in the conventional high voltage semiconductor device 9, a drift region 910 and a body region 920 are formed on the surface side of the substrate 901 within a substrate 901. In addition, a gate region 930 to which a gate voltage is applied and a dummy gate region 940 spaced apart from the gate region 930 are formed on the substrate 901. A different bias voltage from that of the gate region 930 may be applied to the dummy gate region 940.

In this way, by forming the dummy gate region 940 isolated from the gate region 930 other than the gate region 930, the LDMOS semiconductor device 9 having improved breakdown voltage characteristics of the device and low turn on gate charge characteristics may be implemented.

However, since the dummy gate region 940 is formed to be spaced apart from the gate region 930 by a predetermined length, a separation space D1 is created in relation to the gate region 930. Accordingly, during an ion implantation process, for example, to form a source region and/or a drain region after forming the gate region 930 and the dummy gate region 940, an impurity doped region A may be formed on the unwanted side of a substrate 901 due to the separation space D1. In order to prevent the formation of such impurity doped region A, a separate mask pattern needs to be formed to block the separation space D1, which is a factor in reducing process efficiency. Moreover, the above problem may also occur during the process of forming a silicide film in the source region, etc.

To prevent the above-mentioned problems, the inventor of the present disclosure has proposed a novel high voltage semiconductor device with an improved structure and a method of manufacturing the same, the details of which will be described later.

### DOCUMENTS OF RELATED ART

(Patent Document 0001) Korean Patent No. 10-0628250 “POWER SEMICONDUCTOR DEVICE AND METHOD FOR FABRICATING SAME”

### SUMMARY OF THE INVENTION

The present disclosure has been made to solve the problems of the related art, and an objective of the present disclosure is to provide a high voltage semiconductor device and a method of manufacturing the same seeking to prevent breakdown voltage characteristics of the device from deteriorating by preventing the formation of an impurity doped region in a substrate below a gate region and a dummy gate region in a subsequent process by physically connecting one side of the gate region and one side of the dummy gate region to each other.

To be specific, an objective of the present disclosure is to provide a high voltage semiconductor device and a method of manufacturing the same seeking to prevent the upper surface of a substrate under a gate region and a dummy gate region from being exposed to the outside by allowing a first inner gate spacer of the gate region and a second inner gate spacer of the dummy gate region to overlap each other.

An objective of the present disclosure is to provide a high voltage semiconductor device and a manufacturing method thereof seeking to prevent the formation of a second conductivity type impurity doped region in the substrate below a connection part by ensuring that the minimum thickness of the connection part is large compared to the formation depth of a source region and/or a drain region.

The present disclosure may be implemented by an embodiment having the following configuration to achieve the above-described objectives.

According to an embodiment of the present disclosure, there is provided a high voltage semiconductor device, including: a substrate; a drift region within the substrate; a body region within the substrate; a drain region within the drift region; a source region within the body region; a gate region on the substrate; and a dummy gate region with a side thereof connected to the gate region on the substrate.

According to another embodiment of the present disclosure, in the high voltage semiconductor device, the gate region may include: a first gate insulating film on the substrate; a first gate electrode on the first gate insulating film; and a first gate spacer on a sidewall of the first gate electrode, and the dummy gate region may include: a second gate insulating film on the substrate; a second gate electrode on the second gate insulating film; and a second gate spacer on a sidewall of the second gate electrode.

According to still another embodiment of the present disclosure, in the high voltage semiconductor device, the first gate spacer may include a first inner gate spacer on a side adjacent to the second gate region, whereas the second gate spacer may include a second inner gate spacer on a side adjacent to the first gate region, wherein the first inner gate spacer may be physically connected to the second inner gate spacer to form a connection part.

According to still another embodiment of the present disclosure, in the high voltage semiconductor device, the connection part may have a recessed portion as an upper surface of the connection part extends from an adjacent gate electrode and a dummy gate electrode toward a center.

According to still another embodiment of the present disclosure, in the high voltage semiconductor device, the recessed portion may have a distance from a lowermost part of an upper surface thereof to the first gate insulating film and/or the second gate insulating film that satisfies Equation 1.

$$H = \sqrt{{R}^{2} - \frac{{D}^{2}}{4}} \qquad ( Equation 1$$

H: a distance from a lowest end of the recessed portion to the first gate insulating film and/or the second gate insulating film, R: a top and bottom thickness of the first gate electrode and the second gate electrode, D: a separation distance between the first gate electrode and the second gate electrode)

According to still another embodiment of the present disclosure, the high voltage semiconductor device may further include an LDD region in contact with the source region within the body region.

According to still another embodiment of the present disclosure, the high voltage semiconductor device may further include a silicide film on the drain region, the source region, the first gate electrode, and the second gate electrode.

According to still another embodiment of the present disclosure, a high voltage semiconductor device according to the present disclosure includes: a substrate; a drift region on a first side of the substrate; a body region on a second side of the substrate; a drain region within the drift region; a source region within the body region; a first gate electrode on the substrate; a second gate electrode spaced apart from the first gate electrode on the substrate; and a connection part configured to fill a separation space between the first gate electrode and the second gate electrode on the substrate, and include an insulating material, wherein the connection part may have a recessed portion as an upper surface of the connection part extends from the adjacent first gate electrode and the second gate electrode toward a center of the separation space.

According to still another embodiment of the present disclosure, in the high voltage semiconductor device, the recessed portion may have a distance from a bottom of an upper surface thereof to a bottom thereof that is greater than a depth from a surface of the substrate to a bottom of the drain region and/or the source region.

According to still another embodiment of the present disclosure, in the high voltage semiconductor device, the connection part may have a minimum thickness greater than a depth from a surface of the substrate to a bottom of the drain region and/or the source region.

According to still another embodiment of the present disclosure, the high voltage semiconductor device may further include a body contact region contacting the source region within the body region. According to still another embodiment of the present disclosure, in the high voltage semiconductor device, the second gate electrode is electrically connected to a source electrode connected to the source region.

According to still another embodiment of the present disclosure, the high voltage semiconductor device may further include a gate field plate between a bottom of the second gate electrode and the substrate.

According to an embodiment of the present disclosure, there is provided a method of manufacturing a high voltage semiconductor device, the method including: forming a drift region on a surface of a substrate; forming a body region on the surface of the substrate; forming a gate field plate on the surface of the substrate on a drift region side; forming a first gate electrode and a second gate electrode spaced apart from each other on the substrate; and forming a first gate spacer comprising a first inner gate spacer and a second gate spacer comprising a second inner gate spacer by depositing and etching an insulating film to surround the first gate electrode and the second gate electrode on the substrate.

According to another embodiment of the present disclosure, in the method of manufacturing a high voltage semiconductor device, the first inner gate spacer may be physically connected to the second inner gate spacer.

According to still another embodiment of the present disclosure, the method of manufacturing a high voltage semiconductor device may further include: forming a source region within the body region; and forming a drain region within the drift region, and the first inner gate spacer and the second inner gate spacer may be connected to each other to form a connection part, wherein a distance from a bottom of an upper surface of the connection part to a bottom of the connection part may have a larger value than a top and bottom thickness of the source and drain regions.

According to still another embodiment of the present disclosure, in the method of manufacturing a high voltage semiconductor device, the source region may be electrically connected to a source electrode, and the second gate electrode may be electrically connected to the source electrode.

According to still another embodiment of the present disclosure, in the method of manufacturing a high voltage semiconductor device, the first inner gate spacer may overlap the second inner gate spacer.

The present disclosure has the following effects by the above configurations.

According to the present disclosure, it is possible to prevent breakdown voltage characteristics of the device from deteriorating by preventing the formation of an impurity doped region in a substrate below a gate region and a dummy gate region in a subsequent process by physically connecting one side of the gate region and one side of the dummy gate region to each other.

To be specific, according to the present disclosure, it is possible to prevent the upper surface of a substrate under a gate region and a dummy gate region from being exposed to the outside by allowing a first inner gate spacer of the gate region and a second inner gate spacer of the dummy gate region to overlap each other.

Furthermore, according to the present disclosure, it is possible to prevent the formation of a second conductivity type impurity doped region in the substrate below a connection part by ensuring that the minimum thickness of the connection part is large compared to the formation depth of a source region and/or a drain region.

Meanwhile, it should be added that even if effects are not explicitly mentioned herein, the effects described in the following specification expected by the technical features of the present disclosure and their potential effects are treated as if they were described in the specification of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view showing a conventional high voltage semiconductor device;

FIG. 2 is a cross-sectional view showing a high voltage semiconductor device according to an embodiment of the present disclosure;

FIG. 3 is a reference view showing a connection part between a first gate region and a second gate region according to FIG. 2; and

FIGS. 4 to 15 are cross-sectional views showing a method of manufacturing a high voltage semiconductor device according to an embodiment of the present disclosure.

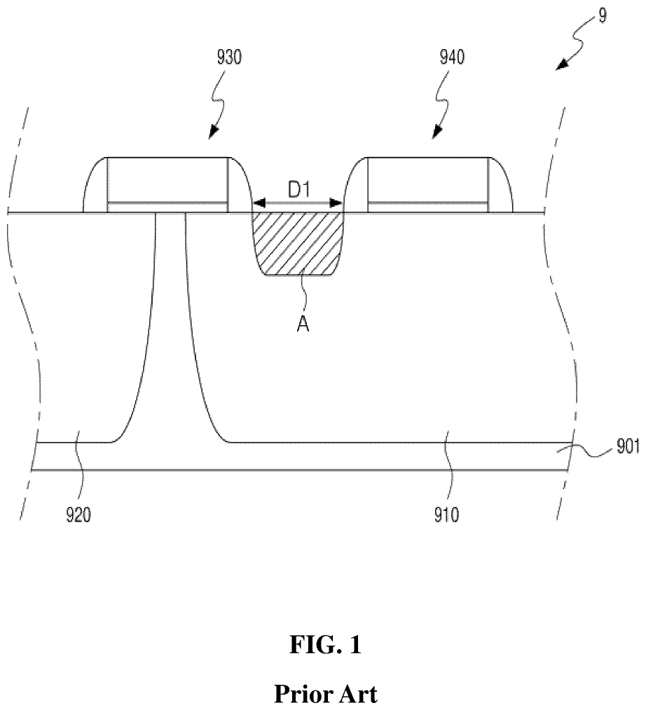

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those of ordinary skill in the art.

Hereinafter, it should be noted that when one component (or layer) is described as being disposed on another component (or layer), one component may be disposed directly on another component, or another component(s) or layer(s) may be located between the components. In addition, when one component is expressed as being directly disposed on or above another component, no other component(s) are located between the components. Moreover, the fact that one component is located “on”, “above”, “below”, or “on one (first) side of”, “on the side of” another component means a relative positional relationship.

The terms first, second, third, etc. may be used to describe various items such as various components, regions and/or parts. However, the items are not limited by these terms.

In addition, it should be noted that, where certain embodiments are otherwise feasible, certain process sequences may be performed other than those described below. For example, two processes described in succession may be performed substantially simultaneously or in the reverse order.

The term a metal oxide semiconductor (MOS) used below is a general term, and “M” is not limited to only metal and may be formed of various types of conductors. Also, “S” may be a substrate or a semiconductor structure, and “O” is not limited to oxide and may include various types of organic or inorganic materials.

In addition, the conductivity type or doped region of the components may be defined as “p-type” or “n-type” according to the main carrier characteristics, but this is only for convenience of description, and the technical spirit of the present disclosure is not limited to what is illustrated. For example, hereinafter, “p-type” or “n-type” will be used as more general terms “first conductivity type” or “second conductivity type”, and here, the first conductivity type means p-type, and the second conductivity type means n-type. Furthermore, it should be understood that “high concentration” and “low concentration” expressing the doping concentration of the impurity region mean the relative doping concentration of one component and another component.

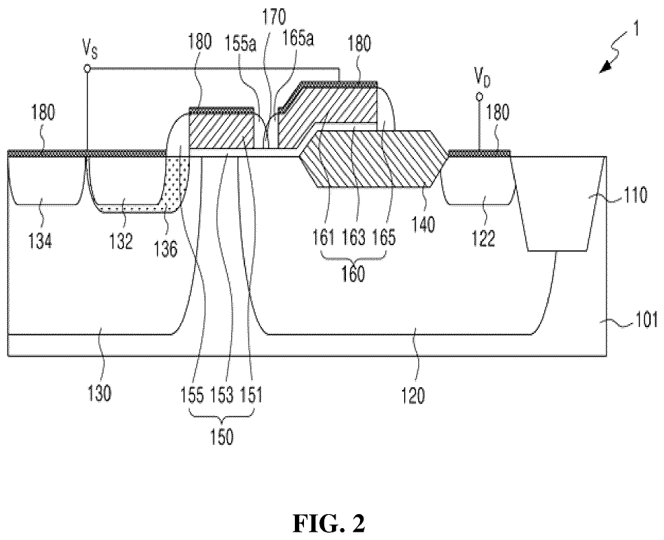

FIG. 2 is a cross-sectional view showing a high voltage semiconductor device according to an embodiment of the present disclosure.

Hereinafter, a high voltage semiconductor device 1 according to an embodiment of the present disclosure will be described in detail with reference to the accompanying drawings. The above “high voltage semiconductor device” may be, for example, an LDMOS device.

Referring to FIG. 2, the present disclosure relates to a high voltage semiconductor device and, more particularly, to a high voltage semiconductor device seeking to prevent breakdown voltage characteristics of the device from deteriorating by blocking the formation of an impurity doped region within a substrate due to a separation space between a gate region and a dummy gate region during a subsequent process by overlapping gate spacers between the gate region and the dummy gate region.

First, a substrate 101 may be formed in the high voltage semiconductor device 1 according to an embodiment of the present disclosure. A well region used as an active region may be formed in the substrate 101, and the active region may be defined by a device isolation layer 110. The substrate 101 may be, for example, a substrate doped with impurities of the first conductivity type, may be a diffusion region disposed in a substrate, or may include an epitaxial layer epitaxially grown on a substrate, and the scope of the present disclosure is not limited by specific examples. The device isolation layer 110 may be formed by a shallow trench isolation (STI) process.

In addition, a drift region 120 may be formed within the substrate 101. The drift region 120 is a region formed at a predetermined depth from the surface of the substrate 101 and, for example, an impurity doped region of the second conductivity type. Although in the drawing, the drift region 120 is spaced apart from the body region 130, which will be described later, at least one side of the drift region 120 may be formed to contact the body region 130, and there is no particular limitation thereon. When the doping concentration in the drift region 120 is below a certain level, the on-resistance characteristics are deteriorated. On the contrary, when the doping concentration is increased above a certain level, the on-resistance characteristics are improved, but breakdown voltage characteristics are deteriorated, thus it is desirable to form an impurity region having an appropriate level of doping concentration in consideration of these characteristics.

A drain region 122 may be formed within the drift region 120. That is, the drain region 122 is a region surrounded by the drift region 120 on the surface side of the substrate 101, and may be an impurity doped region of the second conductivity type. For example, the drain region 122 may be formed between the device isolation film 110 and the gate field plate 140, which will be described later. The drain region 122 is preferably a doped region with a higher concentration of impurities than the drift region 120, and may be electrically connected to a drain electrode VD.

In addition, the body region 130 may be formed within the substrate 101. The body region 130 is a region formed at a predetermined depth from the surface of the substrate 101 and, for example, an impurity doped region of the first conductivity type. As previously mentioned, the body region 130 may be spaced apart from or in contact with the drift region 120, and there is no particular limitation thereon.

A source region 132 and a body contact region 134 may be formed within the body region 130. The source region 132 is, for example, a region doped with a high concentration of impurities of the second conductivity type, and the body contact region 134 is, for example, an impurity doped region of the first conductivity type, and is preferably a region doped with a higher concentration of impurities compared to the body region 130. At this time, both the source region 132 and the body contact region 134 are formed to be surrounded by the body region 130 on the surface side of the substrate 101, and may have sides that are adjacent to or in contact with each other. The source region 132 may be electrically connected to a source electrode VS.

A lightly doped drain (LDD) region 136 may be further formed within the body region 130. The LDD region 136 is an impurity doped region of the second conductivity type and is preferably a doped region with a lower concentration of impurities compared to the source region 132. The LDD region 136 may be formed to contact or overlap the source region 132 and/or the body contact region 134 on the surface side of the substrate 101. In addition, the LDD region 136 may be formed from the surface of the substrate 101 to a shallower depth within the substrate 101 than the source region 132 and/or the body contact region 134, but the scope of the present disclosure is not limited thereto.

In addition, a gate field plate 140 may be formed on the surface side of the substrate 101 to overlap a second gate region 160. For example, the gate field plate 140 may extend from the bottom of the second gate region 160 to the adjacent drain region 122 or to a side adjacent to the drain region 122. As an example, the gate field plate 140 may be formed by a local oxidation of silicon (LOCOS) process. As another example, the gate field plate 140 may be formed by a shallow trench isolation (STI) process. As yet another example, the gate field plate 140 may be formed by a tapered oxide process, and there is no particular limitation thereon. Due to the gate field plate 140, it is possible to prevent an electric field from being concentrated on the edge side of the second gate region 160.

A first gate region 150 and the second gate region 160 may be formed on the substrate 101. The first gate region 150 is a general gate region, and the second gate region 160 may correspond to a dummy gate region. In this way, by limiting the width of the gate region to which the bias voltage is applied to the first gate region 150, the switching speed of the device 1 may be improved by relatively reducing the unit area size of the bottom surface of the first gate region 150. At least one side of the second gate region 160 may be formed on the gate field plate 140, and the first gate region 150 may be formed on a side that does not overlap the gate field plate 140. The first gate region 150 and the second gate region 160 may have sides connected to each other.

The first gate region 150 is formed, for example, on the body region 130, and a channel region may be turned on/off by the gate voltage applied to the first gate region 150. The first gate region 150 includes a first gate electrode 151, and the first gate electrode 151 may include any one of conductive polysilicon, metal, conductive metal nitride, and a combination thereof, and may be formed by a CVD, PVD, ALD, MOALD, or MOCVD process or the like.

In addition, a first gate insulating film 153 may be formed between the first gate electrode 151 and the surface of the substrate 101. The first gate insulating film 153 may include any one of a silicon oxide film, a high dielectric film, and a combination thereof, and may be formed by an ALD, CVP, or PVD process. The first gate insulating film 153 may be connected to a second gate insulating film 163, which will be described later, and there is no particular limitation thereon.

A first gate spacer 155 is formed along each of the sidewalls of the first gate electrode 151, and the first gate spacer 155 may include any one of an oxide film, a nitride film, and a combination thereof. In the illustrated cross-sectional view, the first gate spacer 155 on the side adjacent to the second gate region 160 is referred to as a “first inner gate spacer 155a”. The first gate spacer 155 may have a side that is physically connected to a second gate spacer 165, which will be described later.

The second gate region 160 has at least one side formed on the gate field plate 140 on the substrate 101 and may be electrically connected to the source electrode VS. The second gate region 160 includes a second gate electrode 161, and the second gate electrode 161 may include any one of conductive polysilicon, metal, conductive metal nitride, and a combination thereof, and may be formed by a CVD, PVD, ALD, MOALD, or MOCVD process or the like. Since the second gate electrode 161 is formed in substantially the same process as the first gate electrode 151, the second gate electrode 161 may have substantially the same top and bottom thickness R as the first gate electrode 151.

A second gate insulating film 163 may be formed between the second gate electrode 161 and the surface of the substrate 101. The second gate insulating film 163 may include any one of a silicon oxide film, a high dielectric film, and a combination thereof, and may be formed by an ALD, CVP, or PVD process. The second gate insulating film 163 may be connected to the first gate insulating layer 153, which will be described later.

A second gate spacer 165 is formed along each of the sidewalls of the second gate electrode 161, and the second gate spacer 165 may include any one of an oxide film, a nitride film, and a combination thereof. In the illustrated cross-sectional view, the second gate spacer 165 on the side adjacent to the first gate region 150 is referred to as a “second inner gate spacer 165a”.

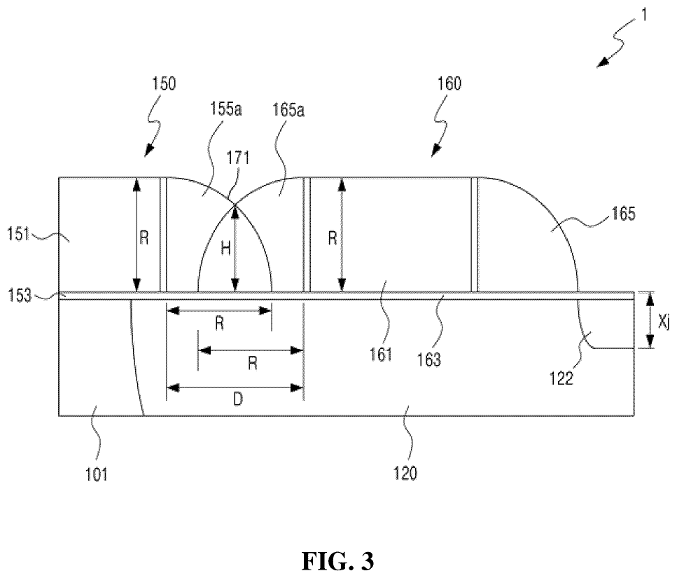

FIG. 3 is a reference view showing a connection part between a first gate region and a second gate region according to FIG. 2.

Referring to FIGS. 2 and 3, the first inner gate spacer 155a and the second inner gate spacer 165a are preferably formed to overlap each other. That is, the first inner gate spacer 155a and the second inner gate spacer 165a may be physically connected to each other. The first inner gate spacer 155a and the second inner gate spacer 165a that overlap each other in this way are referred to as a “connection part 170” (see FIG. 2). The connection part 170 may be formed between the first gate electrode 151 and the second gate electrode 161 on the substrate 101.

In addition, the connection part 170 may have a recessed portion 171 as the upper surface of the connection part 170 extends from the adjacent first gate electrode 151 and the second gate electrode 161 toward the center of the separation space between the first gate electrode 151 and the second gate electrode 161. At this time, it is desirable that a height H from the first gate insulating film 153 and/or the second gate insulating film 163 to the lowest end of the recessed portion 171 has a larger value compared to a depth Xj from the surface of the substrate 101 to the bottom of the drain region 122 and/or the source region 132. That is, by having the value H>Xj, during the ion implantation process to form the drain region 122 and/or the source region 132, the formation of an impurity doped region of the second conductivity type in the substrate 101 below the recessed portion 171 may be prevented. The above term “lowest end of the recessed portion 171” should be understood to mean the side of the recessed portion 171 that has the lowest height from the substrate 101.

Hereinafter, it is assumed that the outer surfaces of the first inner gate spacer 155a and the second inner gate spacer 165a are formed in an arc shape, for example, each having an angle of 90°. In addition, as previously mentioned, both the first gate electrode 151 and the second gate electrode 161 are formed with substantially the same top and bottom thickness R, and considering the separation distance D between the first gate electrode 151 and the second gate electrode 161, the height H from the first gate insulating film 153 and/or the second gate insulating film 163 to the lowest end of the recessed portion 171 may be calculated as in the following equation (1). In this case, it is assumed that the lowest end of the recessed portion 171 is formed at position D/2.

$$H = \sqrt{{R}^{2} - \frac{{D}^{2}}{4}} \qquad ( 1 )$$

In addition, referring to FIG. 2, a silicide film 180 may be formed on the drain region 122, the source region 132, the body contact region 134, the first gate electrode 151, and the second gate electrode 161. The silicide film 180 may be formed by a self-aligned silicide (salicide) process to improve contact resistance and thermal stability, and may include a metal film such as cobalt (Co), nickel (Ni), or titanium (Ti).

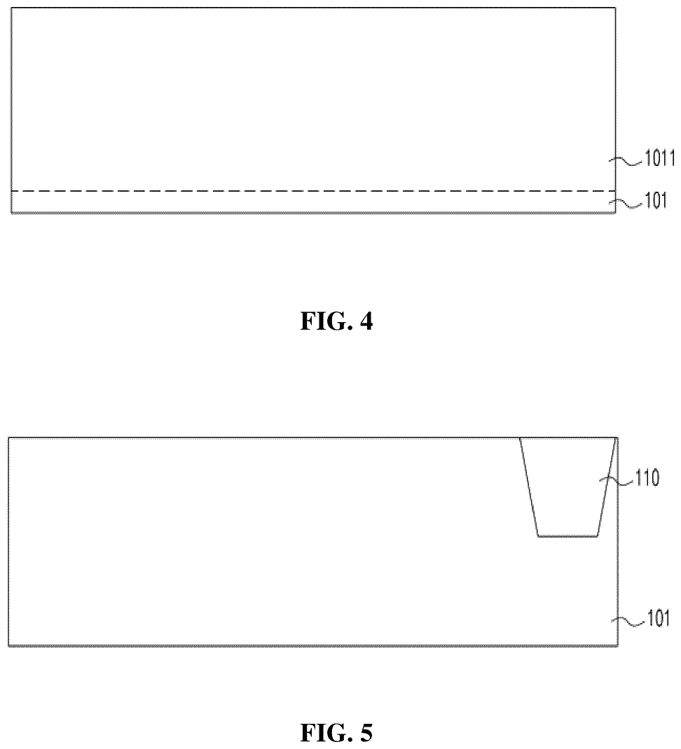

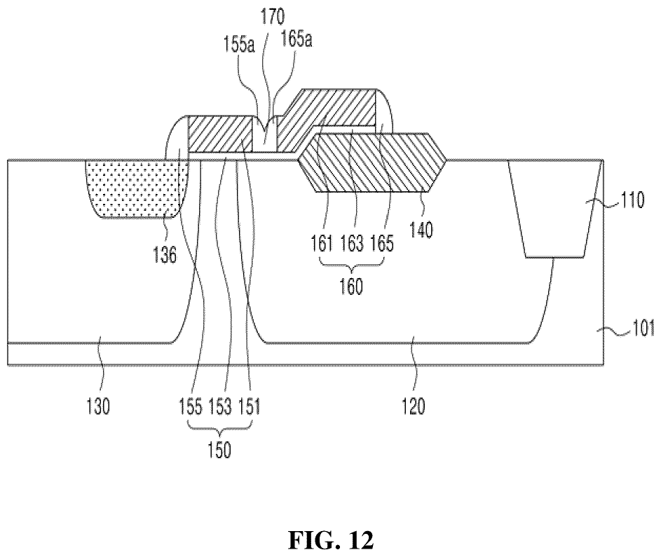

FIGS. 4 to 15 are cross-sectional views showing a method of manufacturing a high voltage semiconductor device according to an embodiment of the present disclosure.

Hereinafter, a method of manufacturing a high voltage semiconductor device according to an embodiment of the present disclosure will be described in detail with reference to the attached drawings.

Referring to FIG. 4, first, an epitaxial layer 1011 is formed on a substrate 101 through epitaxial growth. Hereinafter, “substrate” is understood as a substrate on which the epitaxial layer 1011 is grown.

Thereafter, referring to FIG. 5, a device isolation layer 110 may be formed within the substrate 101. The device isolation layer 110 may be formed by a shallow trench isolation (STI) process, and an active region may be defined by the device isolation layer 110.

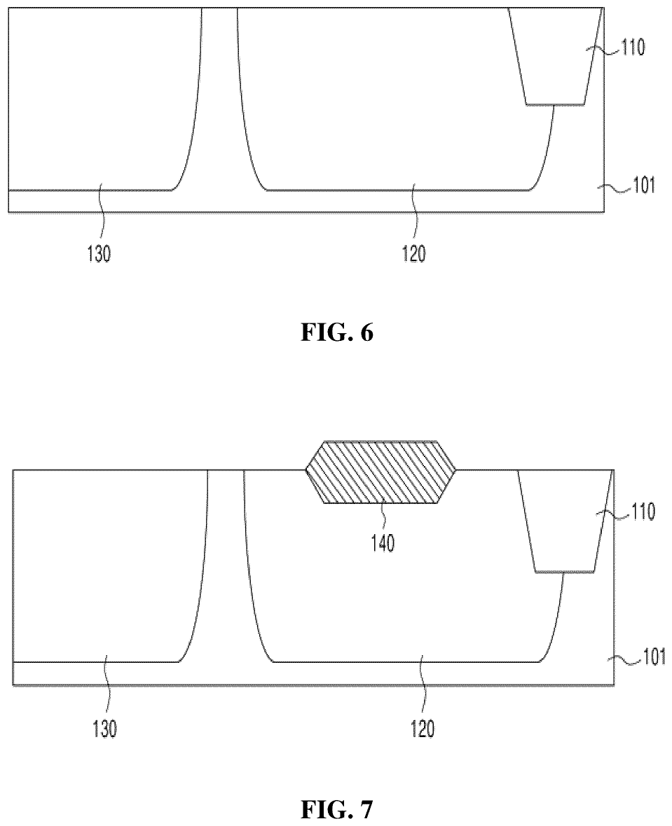

Referring to FIG. 6, after forming the device isolation layer 110, a drift region 120 and a body region 130 may be formed within the substrate 101. The drift region 120 and the body region 130 are formed through individual processes, and in each process, the drift region 120 and the body region 130 are formed through an ion implantation process using a mask pattern (not shown).

Thereafter, referring to FIG. 7, a gate field plate 140 may be formed on the surface of the substrate 101. As previously mentioned, the gate field plate 140 may be formed by a local oxidation of silicon (LOCOS) process, a shallow trench isolation (STI) process, or a tapered oxide process, and the scope of the present disclosure is not limited by specific examples.

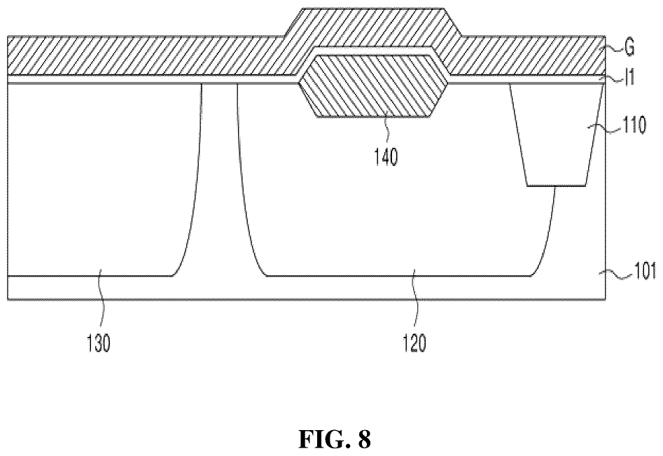

Thereafter, referring to FIG. 8, a first insulating film I1 and a gate film G may be sequentially formed. That is, the first insulating film I1 may be formed on the substrate 101 and the gate field plate 140, and then the gate film G may be formed on the first insulating film I1. The first insulating film I1 may include any one of a silicon oxide film, a high dielectric film, and a combination thereof. The gate film G may include any one of conductive polysilicon, metal, conductive metal nitride, and a combination thereof.

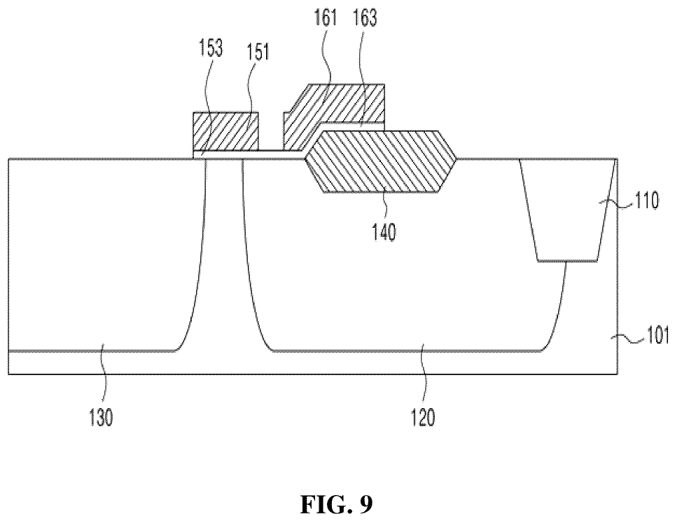

Referring to FIG. 9, after forming a mask pattern (not shown) on the gate film G, a first gate electrode 151 and a second gate electrode 161 may be formed by etching the gate film G. In addition, by etching the first insulating film I1, a first gate insulating film 153 and a second gate insulating film 163 may be formed.

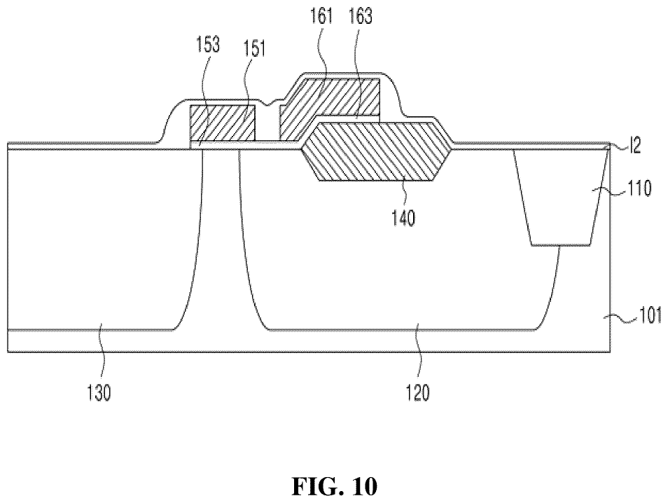

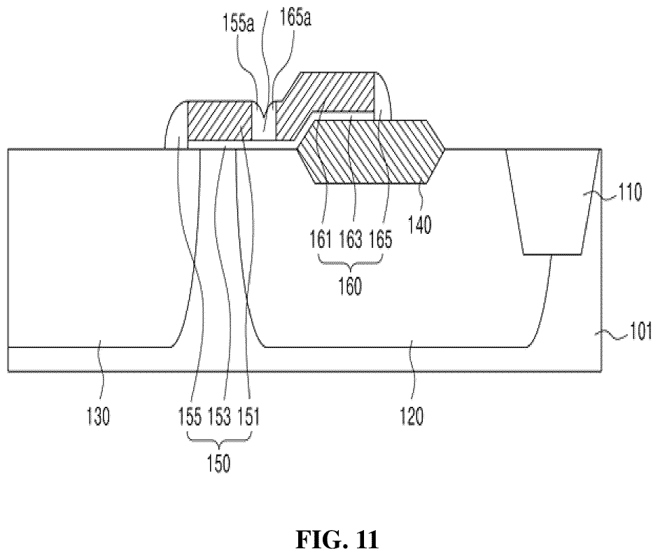

Thereafter, referring to FIG. 10, a second insulating film 12 is deposited on the sides of the first gate electrode 151 and the second gate electrode 161, for example, by a chemical vapor deposition (CVD) process, and referring to FIG. 11, by etching, for example, by an anisotropic dry etching process, a first gate spacer 155 and a second gate spacer 165 may be formed. As previously described, when a first inner gate spacer 155a and a second inner gate spacer 165a overlap each other to form a connection part 170, the connection part 170 closes the substrate 101 therebelow and may prevent impurities from being doped into the substrate 101 during a subsequent process. Thus, referring to FIG. 11, lightly doped drain (LDD) region 136 within the body region 130 may be formed through an ion implantation process without forming a separate photoresist film between the first gate electrode 151 and the second gate electrode 161.

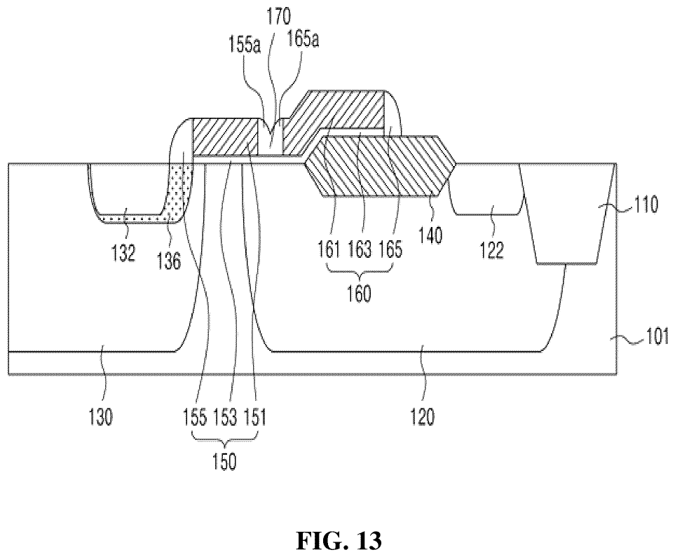

Referring to FIG. 13, in a subsequent process, without forming a separate photoresist film between the first gate electrode 151 and the second gate electrode 161, through an ion implantation process, a drain region 122 and a source region 132 may be formed. The drain region 122 may be formed in the drift region 120, and the source region 132 may be formed in the body region 130. At this time, it is desirable that a height H from the first gate insulating film 153 and/or the second gate insulating film 163 to the lowest end of a recessed portion 171 has a larger value compared to a depth Xj from the surface of the substrate 101 to the bottom of the drain region 122 and/or the source region 132. Due to this, it is possible to prevent impurities of the second conductivity type from being doped into the substrate 101 below the connection part 170 when forming the drain region 122 and the source region 132.

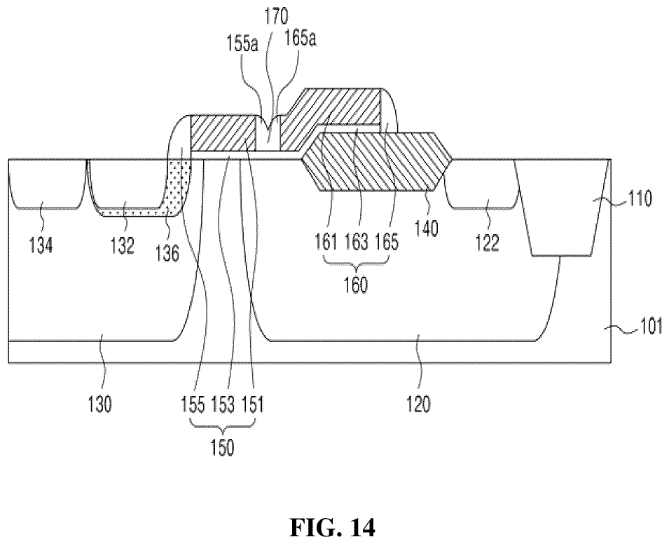

Referring to FIG. 14, after the source region 132 is formed in the body region 130, a body contact region 134, which is a high concentration impurity doped region of the first conductivity type, may also be formed in the body region 130.

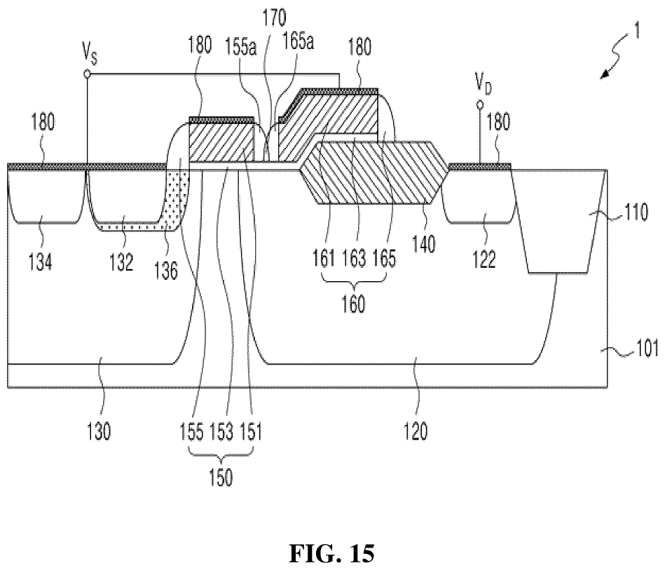

Thereafter, referring to FIG. 15, in order to improve contact resistance and thermal stability, a self-aligned silicide (salicide) process may be performed to form a silicide film 180 on the upper surfaces of the drain region 122, the source region 132, the body contact region 134, the first gate electrode 151, and the second gate electrode 161 using a metal film such as cobalt (Co), nickel (Ni), or titanium (Ti). During this silicide process, since the substrate 101 below the connection part 170 is blocked by the connection part 170, there is no need to form a separate photoresist film between the first gate region 150 and the second gate region 160.

The above detailed description is illustrative of the present disclosure. In addition, the above description shows and describes preferred embodiments of the present disclosure, and the present disclosure can be used in various other combinations, modifications, and environments. That is, changes or modifications are possible within the scope of the concept of the disclosure disclosed herein, the scope equivalent to the written disclosure, and/or within the scope of skill or knowledge in the art. The above-described embodiment describes the best state for implementing the technical idea of the present disclosure, and various changes required in the specific application field and use of the present disclosure are possible. Accordingly, the detailed description of the present disclosure is not intended to limit the present disclosure to the disclosed embodiments.

What is claimed is:

1. A high voltage semiconductor device comprising:
a substrate;
a drift region disposed within the substrate;
a body region disposed within the substrate;
a drain region disposed within the drift region;
a source region disposed within the body region;
a gate region disposed on the substrate; and
a dummy gate region having a side connected to the gate region disposed on the substrate.

2. The high voltage semiconductor device of claim 1,
wherein the gate region comprises:
a first gate insulating film disposed on the substrate;
a first gate electrode disposed on the first gate insulating film; and
a first gate spacer disposed on a sidewall of the first gate electrode, and
wherein the dummy gate region comprises:
a second gate insulating film disposed on the substrate;
a second gate electrode disposed on the second gate insulating film; and
a second gate spacer disposed on a sidewall of the second gate electrode.

3. The high voltage semiconductor device of claim 2,
wherein the first gate spacer comprises a first inner gate spacer on a side adjacent to the dummy gate region, whereas the second gate spacer comprises a second inner gate spacer on a side adjacent to the gate region, and
wherein the first inner gate spacer is physically connected to the second inner gate spacer to form a connection part.

4. The high voltage semiconductor device of claim 3,
wherein the connection part has a recessed portion defined by an upper surface of the connection part extending from the first gate electrode and the second gate electrode toward a center of the connection part.

5. The high voltage semiconductor device of claim 4,
wherein the recessed portion has a distance from a lowermost part of an upper surface of the recessed portion to the first gate insulating film and/or the second gate insulating film according to Equation 1:
$$H = \sqrt{{R}^{2} - \frac{{D}^{2}}{4}} ,$$
wherein H denotes the distance from the lowermost part of the recessed portion to the first gate insulating film and/or the second gate insulating film, R denotes a top to bottom thickness of the first gate electrode or the second gate electrode, D denotes a distance between the first gate electrode and the second gate electrode.

6. The high voltage semiconductor device of claim 4, further comprising:
an LDD region in contact with the source region, the LDD region being disposed within the body region.

7. The high voltage semiconductor device of claim 4, further comprising:
a silicide film disposed on the drain region, the source region, the first gate electrode, and the second gate electrode.

8. A high voltage semiconductor device comprising:
a substrate;
a drift region disposed on a first side of the substrate;
a body region disposed on a second side of the substrate;
a drain region disposed within the drift region;
a source region disposed within the body region;
a first gate electrode disposed on the substrate;
a second gate electrode disposed apart from the first gate electrode on the substrate; and
a connection part filling a separation space between the first gate electrode and the second gate electrode on the substrate, the connection part including an insulating material,
wherein the connection part has a recessed portion defined by an upper surface of the connection part extending from the first gate electrode and the second gate electrode toward a center of the separation space.

9. The high voltage semiconductor device of claim 8,
wherein the recessed portion has a distance from a lowermost part of an upper surface of the recessed portion to a bottom surface of the recessed portion that is greater than a depth from a surface of the substrate to a bottom of the drain region and/or the source region.

10. The high voltage semiconductor device of claim 8,
wherein the connection part has a minimum thickness greater than a depth from a surface of the substrate to a bottom of the drain region and/or the source region.

11. The high voltage semiconductor device of claim 8, further comprising:
a body contact region contacting the source region within the body region.

12. The high voltage semiconductor device of claim 8,
wherein the second gate electrode is electrically connected to a source electrode connected to the source region.

13. The high voltage semiconductor device of claim 8, further comprising:
a gate field plate disposed between a bottom of the second gate electrode and the substrate.

14. A method of manufacturing a high voltage semiconductor device, the method comprising:
forming a drift region on a surface of a substrate;
forming a body region on the surface of the substrate;
forming a gate field plate on the surface of the substrate on a drift region side;
forming a first gate electrode and a second gate electrode spaced apart from each other on the substrate; and
forming a first gate spacer comprising a first inner gate spacer and a second gate spacer comprising a second inner gate spacer by depositing and etching an insulating film to surround the first gate electrode and the second gate electrode on the substrate.

15. The method of claim 14,
wherein the first inner gate spacer is physically connected to the second inner gate spacer.

16. The method of claim 15, further comprising:
forming a source region within the body region; and
forming a drain region within the drift region, and
the first inner gate spacer and the second inner gate spacer are connected to each other to form a connection part,
wherein a distance from a lowermost part of an upper surface of the connection part to a bottom surface of the connection part has a larger value than a top to bottom thickness of the source region and/or drain region.

17. The method of claim 16,
wherein the source region is electrically connected to a source electrode, and the second gate electrode is electrically connected to the source electrode.

18. The method of claim 16,
wherein the first inner gate spacer overlaps the second inner gate spacer.
